(19) United States
(12) Patent Application Publication
(10) Pub. No.: US 2026/0130124 A1
(43) Pub. Date: May 7, 2026

(54) PLANAR ELECTRICALLY FLOATING QUBIT CIRCUIT STRUCTURE

(71) Applicant: FORSCHUNGSZENTRUM JÜLICH GMBH, Jülich (DE)

(72) Inventor: Rami BARENDS, Heerlen (NL)

(21) Appl. No.: 19/118,984

(22) PCT Filed: Oct. 10, 2023
(86) PCT No.: PCT/EP2023/077982

§ 371 Date: Apr. 7, 2025

(30) Foreign Application Priority Data
Oct. 11, 2022 (EP) 22 200 935.9

(51) Int. Cl. H10N 60/12; H10N 60/83

(52) U.S. Cl. CPC H10N 60/12; H10N 60/83

(57) ABSTRACT

A planar electrically floating qubit circuit structure including a Josephson junction region galvanically coupled to first and second electrode regions and a ground electrode region is configured so as to result in a series capacitance of the first and second electrode regions to the ground electrode region that is greater than the self-capacitance of the Josephson junction region.

The invention relates to a planar electrically floating qubit circuit structure comprising a Josephson junction region including first and second weakly coupled superconductors; first and second electrode regions galvanically coupled to said first and second superconductors, respectively; and a ground electrode region.

Quantum circuits including a Josephson junction having a self-capacitance and an external shunt capacitance connected thereacross are generally known. In particular, transmon qubits that are currently widely used are generally implemented using a dominant direct capacitor in parallel with either a single Josephson junction for fixed-frequency qubits, or two Josephson junctions in a superconducting quantum interference device (SQUID) geometry. These qubits are straight forward to build, however, they suffer from a lack of coherence.

To remedy the coherence problem, it has been a conventional approach to use extended, large capacitors directly connected across the superconductors of the Josephson junction. In this case, the electric fields are low so that individual coupling to defects in the capacitive area is minimised. This can, however, induce parasitic couplings in large systems. Moreover, using such large capacitors complicates implementing coupling schemes between qubits, resonators, and other elements, due to the size needed for coupling capacitors.

An article entitled “Merged-element transmon” published by R. Zhao, S. Park, T. Zhao, M. Bal, C. R. H. McRae, J. Long, and D. P. Pappas (Phys. Rev. Applied 14, 064006 (2020)) proposes to implement the circuit structure by engineering the Josephson junction self-capacitance to be large enough to act as its own shunt capacitor, thereby eliminating the need for the external direct capacitor.

It is an object of the present invention to propose an alternative implementation of a qubit circuit structure of the above referenced type.

In order to attain this object, a circuit structure of the above referenced type is implemented with the series capacitance of said first and second electrode regions to said ground electrode region being greater than the self-capacitance of said Josephson junction region.

In the planar circuit structure of the invention, the first and second electrode regions are mutually galvanically isolated and each of them is also galvanically isolated from the coplanar ground electrode. In particular, the isolation is effected by an isolation zone that is free from electrode material and is located between the ground electrode region and the first and second electrode regions so as to physically separate them from each other. This is preferably realized by a thin metallization layer formed on the plain surface of an underlying substrate and having cut-outs formed therein that spatially separate the ground electrode region and the first and second electrode regions from each other. In particular, these cut-outs are in the shape of thin strips that are free of metallization material.

In this configuration, capacitances between the ground electrode region and the first and second electrode regions, respectively, form a series capacitance that shunts the self-capacitance of the Josephson junction region. The capacitance value of this arrangement may be calculated in accordance with a method disclosed in arXiv:1410.3458 entitled “Calculation of Coupling Capacitance in Planar Electrodes”.

The circuit structure according to the invention is configured so as to result in a value of the series capacitance that is greater than the value of the self-capacitance of the Josephson junction region. In practice, the proportion of the self-capacitance in the total capacitance may be not more than 40%, preferably not more than 30%, or 20% or even 10%.

As compared to prior art using a dominant direct capacitor in parallel with a Josephson junction, the circuit structure according to the invention results in better coherence. There is less coupling to individual dipole defects (as for instance described in an article by J. M. Martinis, K. B. Cooper, R. McDermott, M. Steffen, M. Ansmann, K. D. Osborn, K. Cicak, S. Oh, D. P. Pappas, R. W. Simmonds, and C. C. Yu, Phys. Rev. Lett. 95, 210503 (2005) entitled “Decoherence in Josephson Qubits from Dielectric Loss”), as it requires more ground capacitance and hence less electrical field strength. It is easier to implement coupling to drivelines, qubits or other elements, as the implementation has longer traces. In addition, parasitic crosstalk to other qubits is reduced. Larger distance between the qubits means that qubits are farther away from the other qubits “center of mass”. Further, parasitic coupling and related loss to other grounds and metals on other planes for 3D-integrating systems is reduced thanks to the direct capacitance to ground. The circuit structure according to the invention can be straight forwardly implemented using waveguides, and the parasitic inductance is small.

The invention is not limited to qubit circuit structures comprising a single Josephson junction for fixed-frequency qubits but in particular also applies to circuit structures having two Josephson junctions in a superconducting quantum interference device (SQUID) geometry.

In particular, the surface area of the Josephson junction region is less than the surface area of each of the first and second electrode regions. Preferably, each of the first and second electrode regions is bonded by two curve segments that extend between a first point that is nearest to the Josephson junction region and a second point that is remotest from the Josephson junction region, and for each point on a bisector curve that extends between the two curve segments from the first to the second point, a distance between the two curve segments measured along a transversal straight line orthogonally intersecting the bisector curve in that point is not substantially increased when the distance of that intersection point from the Josephson junction region is decreased. This is very different from standard qubit designs which feature large electrode pads in the center of the circuit structure.

In preferred embodiments, the geometrical arrangement of said first and second electrode regions is centrally symmetric with respect to the centroid of the surface area of said Josephson junction region. This point symmetric geometry maintains the electrical “center of mass” and minimizes parasitics from asymmetry.

In other expedient designs, each of said first and second electrode regions is in the shape of a continuous strip of essentially uniform width that extends between a connecting portion thereof, that is located adjacent to said Josephson junction region for galvanic connection thereto and at least one free end portion thereof, that is located remote from said Josephson junction region. In these designs, the before-mentioned bisector curve may in particular be a straight line, a line composed of straight line sections, a meandering line and/or combinations thereof. The longitudinal edges of the strip extend along the bisector curve on both sides thereof at a uniform distance. From these edges of the strip, neighboring edges of the ground electrode region are preferably equidistantly spaced at a small distance. The transverse edge that connects the longitudinal edges of the strip at an end portion thereof is preferably at the same distance away from the corresponding neighboring edge of the ground plain.

In a preferred embodiment, said strip has first and second free end portions with said connecting portion of said strip located half-way therebetween. Especially preferably, the directions of extension of said strip from its connecting portion to its first and second free end portions are essentially mutually orthogonal. In the latter case, the connecting portion of the strip is expediently formed as a short strip section whose bisector curve extends in a direction that is orthogonal to the angular bisector of the two orthogonal directions of strip extension. Specifically, as already stated earlier, the connecting portion may have one, two or even more Josephson junctions connected thereto. One of the benefits of this design is its increased compactness.

In any of the above realizations of the first and second electrode regions that may be described as having the connecting portion located between legs extending therefrom, it is to be understood that instead of two open-ended legs as described above, in principle more legs can be added, depending on the need for coupling to other elements or drivelines.

In particular, said direction of extension of said strip is a mean linear direction, said strip meandering about said linear direction between said connecting portion thereof and each one of said free end portions thereof.

According to another aspect of the invention, said ground electrode region and each of said first and second electrode regions is arranged so as to form a microstrip waveguide, or as an alternative, said ground electrode region and each of said first and second electrode regions is arranged so as to form a coplanar waveguide. Other waveguide geometries that include direct capacitance to ground are possible.

The qubit circuit structure according to the invention may in particular be implemented as a fixed-frequency transmon, specifically including one single Josephson junction, or as a tuneable transmon, specifically including two Josephson junctions.

In a further aspect, a circuit structure according to the invention is combined with a tuneable coupler and another circuit structure according to the invention so that at least one of said first and second electrode regions of the one of said circuit structures is capacitively coupled to the tuneable coupler that is capacitively coupled to one of said first and second electrode regions of the other one of said circuit structures.

In a useful embodiment of this further aspect said at least one free end portion of said strip forming one of said first and second electrode regions of said one of said circuit structures and said at least one free end portion of said strip forming one of said first and second electrode regions of said other one of said circuit structures are located adjacent to said coupler for capacitive coupling thereto.

In the circuit structure of this embodiment, the interaction between the coupler and the one qubit circuit structure that forms a first qubit is mediated by the strip associated to the first qubit, while the interaction between the coupler and the other qubit circuit structure forming a second qubit is mediated by the strip associated with the second qubit. In particular, the capacitance between the two strips determines a direct capacitive coupling between the two qubits while the capacitance between the coupler and the strips associated with the first and second qubits determines the coupling between the coupler and the first and second qubits, respectively. Finally, the capacitance between the coupler and the ground electrode region determines the self-capacitance of the coupler. The geometry of the embodiment according to the invention enables to select dimensions so as to obtain desired values of these capacitances. Typically, the value of the direct coupling between the qubits is in the region of 0.1 fF, the value of the coupling between the coupler and each of the qubits is in the region of 6 fF, and the value of the self-capacitance of the coupler is in the region of 80 fF.

In an expedient embodiment, a distance between said free end portions is dimensioned so as to result in a desired value of the capacitive coupling, specifically, values in the region of 0.1 fF may be obtained by dimensioning the distance in the region of 100 μm.

In a useful embodiment, the strips that extend between said connecting portions and said at least one free end portions extend along a common linear center line.

In another useful embodiment, said coupler is connected to a third electrode region that is capacitively coupled to said common ground electrode region and to said first and second electrode regions that are capacitively coupled to said coupler, said third electrode region being dimensioned so as to result in desired values of the self-capacitance of the coupler and the coupling capacitances between said qubits and said coupler, respectively. By appropriately dimensioning the third electrode region, desired values of the capacitive coupling between the coupler and each of the two qubits may be obtained, specifically in the region of 6 fF. In addition, a desired value of the self-capacitance of the coupler may be obtained, specifically in the region of 80 fF.

In a geometrically expedient embodiment, said third electrode region extends adjacent to and along the strips whose free end portions are located adjacent to said coupler, more specifically, the third electrode region is in the shape of a strip of essentially uniform width that longitudinally extends alongside the strips whose free end portions are located adjacent to said coupler. Alternatively, the third electrode region is in the shape of first and second strips of essentially uniform width that longitudinally extend on both sides alongside the strips whose free end portions are located adjacent to said coupler.

In major embodiments, said ground electrode region and at least one of said first, second and third electrode regions, respectively, extend in a common plane with adjacent boundaries thereof defining an insulating gap therebetween. Specifically, all of said first, second and third electrode regions are in a common plane with said ground electrode region.

In the following, exemplary embodiments of the invention will be described with reference to the drawings, in which:

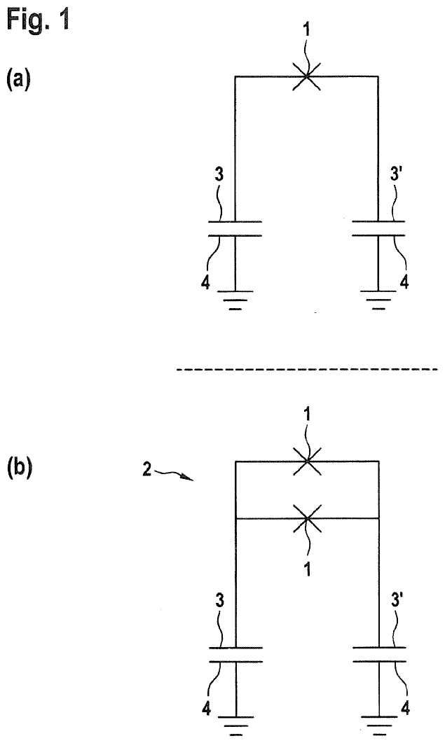

FIGS. 1(a) and (b) show a schematic circuit diagram of a fixed-frequency implementation using a single Josephson junction and a tuneable-frequency implementation using a SQUID, respectively, in accordance with the invention;

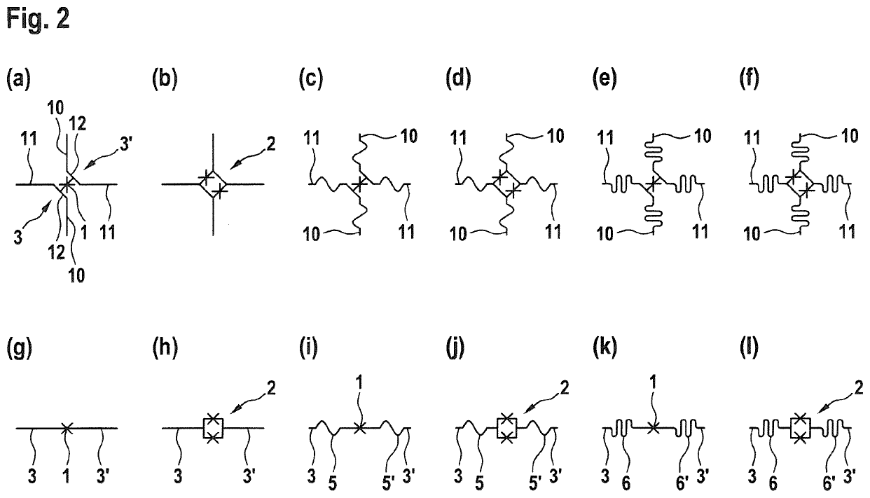

FIGS. 2(a) to (l) schematically illustrate various geometric shapes of first and second electrode regions galvanically coupled to Josephson junction regions;

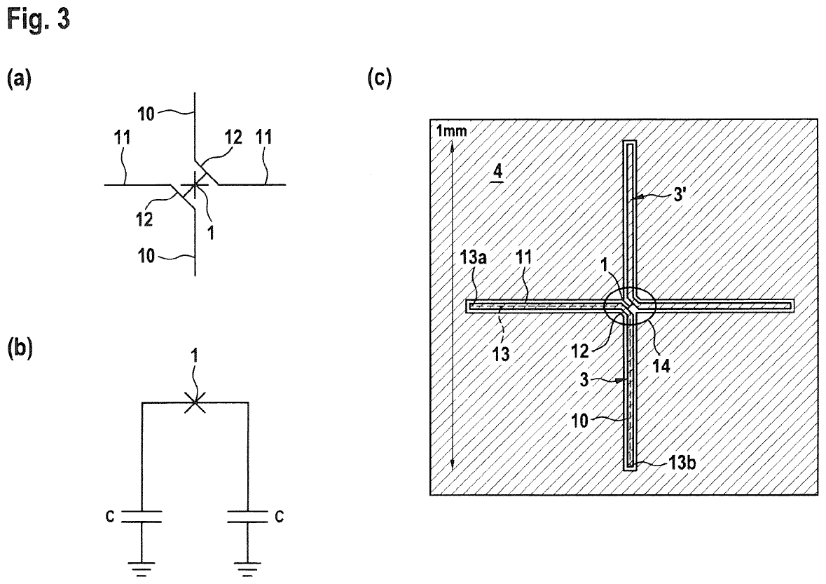

FIGS. 3(a), (b) and (c) illustrate the schematic geometric shape according to FIG. 2a, a corresponding schematic circuit diagram and a more detailed plan view of an example implementation, respectively;

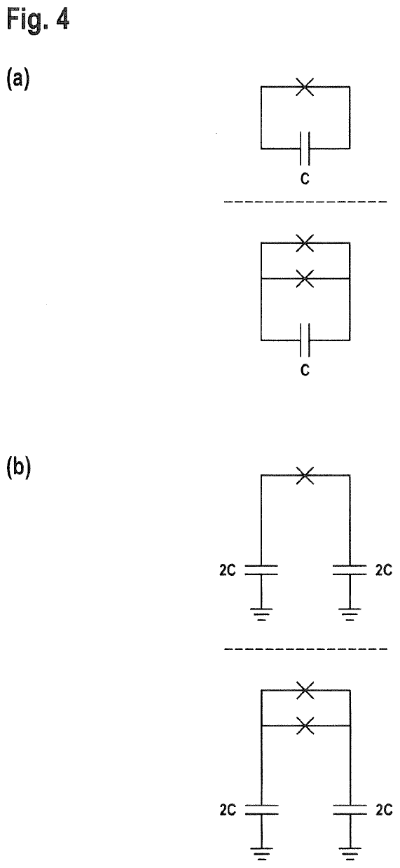

FIGS. 4(a) and 4(b) illustrate a comparison between standard qubit circuits using a dominant direct capacitor between electrodes and embodiments according to the invention;

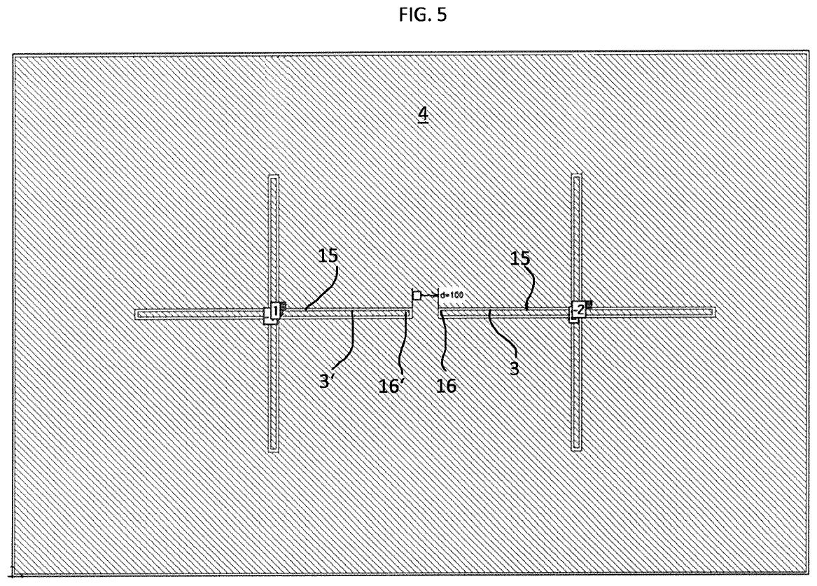

FIG. 5 illustrates direct capacitive coupling between two implementations according to FIG. 3(c);

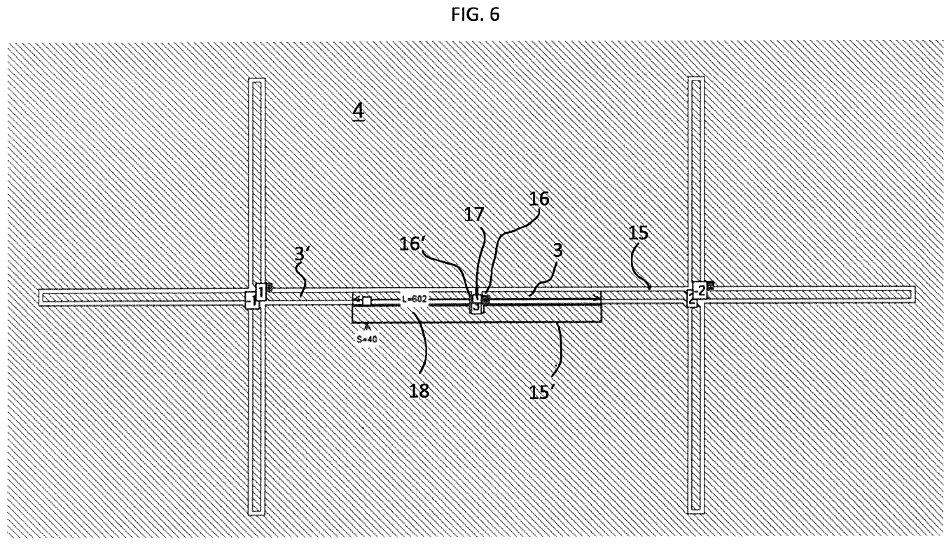

FIG. 6 illustrates a modification of the embodiment of FIG. 5 having a coupler arranged between the two implementations of FIG. 3(c); and

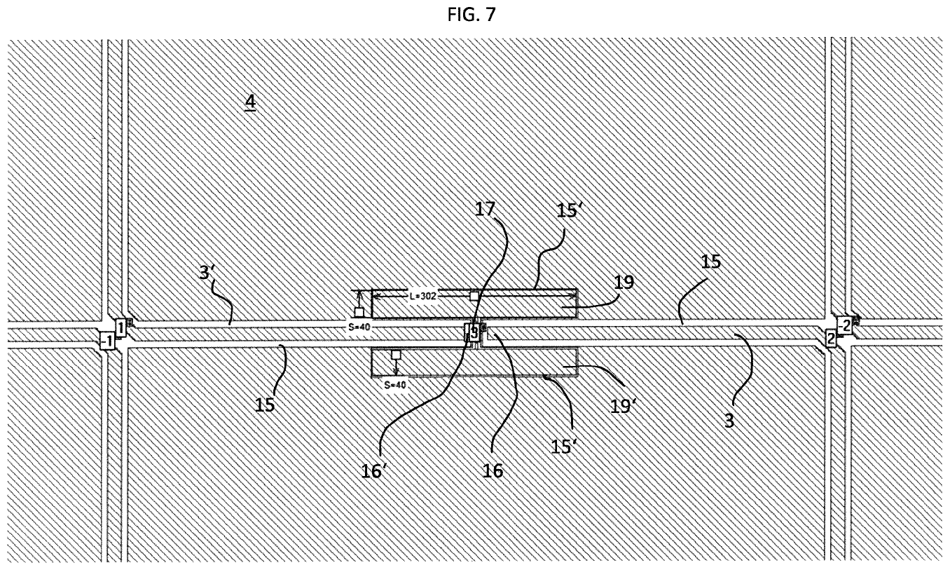

FIG. 7 illustrates a further modification of the embodiment of FIG. 6.

In the circuit diagrams of FIGS. 1(a) and (b), a cross symbol stands for a Josephson junction region 1 including first and second weakly coupled superconductors. The Josephson junction 1 of FIG. 1(a) or a SQUID-loop 2 composed of the two Josephson junctions 1 in FIG. 1(b) are each galvanically coupled to first and second electrode regions 3, 3′ that are symbolized by each one of the capacitor plates of two capacitors. The opposite ones 4 of the two capacitor plates 3, 3′ are to symbolize a common ground electrode region 4. The first and second electrode regions 3, 3′ thereby imply a series capacitance to the ground electrode region 4. The first and second electrode regions 3, 3′ and the ground electrode region 4 are in a coplanar configuration that is arranged and dimensioned so as to have a series capacitance greater than the self-capacitance of the Josephson junction region 1 or SQUID-loop 2, respectively.

FIGS. 2(a) to (l) illustrate various types of geometric shapes of the first and second electrode regions 3, 3′ that may expediently be used to implement the invention. The coplanar ground electrode region is not indicated in this illustration but may be imagined to fill the remaining area of each of the implementations so as to leave some gap to the first and second electrode regions 3, 3′ as well as the Josephson junction region 1. A more detailed illustration of this situation will be discussed later with reference to FIG. 3(c).

In the embodiment illustrated in FIG. 2(g) each of the first and second electrode regions 3, 3′ is in the shape of a rectilinear strip of identical width and length having one end thereof galvanically connected to the Josephson junction region 1 and the opposite end being open. FIG. 2(h) illustrates a similar geometry and is only different from FIG. 2(g) in that the connection is to a SQUID-loop 2 instead of a single Josephson junction 1. The embodiments of FIGS. 2(i) and (j) correspond to the ones of FIGS. 2(g) and (h), respectively, however, with the difference that the strips 3, 3′ are not rectilinear but each include an intermediate section 5, 5′ of a sine wave-like shape. The embodiments of FIGS. 2(k) and (l) are similar to the ones of FIGS. 2(i) and (j), respectively, however, with the difference that the sine wave-like intermediate sections 5, 5′ are replaced by intermediate sections 6, 6′, each of which meanders over a length of two periods of a waveform composed of essentially transverse rectilinear sections intermittently connected by rounded arcs at their ends. As can be seen from the drawings, each of the embodiments of FIGS. 2(g) to 2(l) have a centrally symmetric design with respect to the centroid of the surface area of the Josephson junction region 1 or SQUID-loop region 2, respectively.

As may be taken from FIG. 2, each of the above-described embodiments illustrated in FIGS. 2(g) to (l) may generally be described to have a Josephson junction 1 or a SQUID-loop 2 in the center thereof and two rectilinear or meandering legs 3, 3′ extending from the center in opposite directions. In contrast, in each of the embodiments illustrated in FIG. 2(a) to (f) each of the first and second electrode regions 3, 3′ comprises a pair of legs 10, 11 and a connecting portion 12 linking the legs 10, 11 in the neighborhood of the Josephson junction region 1 or SQUID-loop area 2. The legs 10, 11 of each pair extend in mutually orthogonal directions. Otherwise, the shape of the legs 10, 11 in FIGS. 2(a) to (f) is similar to the shape of the first and second electrode regions 3, 3′ illustrated in FIGS. 2(g) to (l). Thereby, each of the embodiments of FIGS. 2(a) to 2(f) is again centrally symmetric with respect to the centroid of the surface area of the Josephson junction region 1 or the SQUID-loop region 2, respectively.

FIG. 3 shows an embodiment according to FIG. 2(a) in more detail, with FIG. 3(a) schematically illustrating the geometry, FIG. 3(b) illustrating the equivalent circuit diagram and FIG. 3(c) illustrating the circuit layout in an enlarged scale. As may be seen from FIG. 3(c), the legs 10, 11 and the connection portion (12) of the first and second electrode regions 3, 3′ extend at an essentially constant transverse width along a bisector curve 13 that is marked as a dotted line in the first electrode region 3 that extends in the lower left portion of FIG. 3(c), while the same, although not explicitly drawn-in, also applies to the second electrode region 3′ extending in the upper right portion of FIG. 3(c). This bisector curve 13 extends from a left outermost point 13a towards a central portion that is indicated by circle 14 and then again towards a lower outermost point 13b. The Josephson junction region 1 is located centrally within circle 14 and covers a surface area that is much smaller than the surface area covered by the first and second electrode regions 3, 3′. The first and second electrode regions 3, 3′ are centrally symmetric with respect to the centroid of the surface area of the Josephson junction 1 so that the foregoing description of the first electrode region 3 applies accordingly.

As may be further seen from FIG. 3(c), the Josephson junction region 1 is galvanically connected to the first and second electrode regions 3, 3′ where the respective connecting portions 12 are closest thereto. While the portions of the bisector curve 13 that extend from the outermost points 13a, 13b towards the central portion 14 are mutually orthogonal, the section of the bisector curve 13 within the connecting portion 12 is orthogonal to the angular bisecting line between the two orthogonal sections of bisector curve 13.

The above described first and second electrode regions 3, 3′ are illustrated in FIG. 3(c) as hatched areas of metallization. The remaining hatched area of FIG. 3(c) indicates the metallized ground electrode region 4. It is separated from the first and second electrode regions 3, 3′ by a small transverse gap 15 that extends into the area limited between the facing edges of the connecting portions 12 of the first and second electrode regions 3, 3′ and is free from any metallization. Because of the centrally symmetric configuration, capacitances defined between the ground electrode region 4 and the first and second electrode regions 3, 3′, respectively, are identical and are indicated as “C” in FIG. 3(b).

FIG. 4 is to exemplarily illustrate circuit parameters of an implementation in accordance with the invention as shown in FIG. 4(b) as compared to the ones of a conventional transmon circuit comprising a large capacitor to directly shunt the Josephson junction 1 as shown in FIG. 4(a). Standard parameters of the conventional circuit are C=80 fF, effective Josephson induction is 13 nH, and operating frequency is 5 GHz.

In the implementation according to the invention to have the same shunt capacitance, each of the capacitances of the first and second electrode regions to ground has the value 2C. When implemented with coplanar waveguides, on Si with S/W=2 ratio for the CPW, the capacitance per unit length is 0.18 nF/m, the inductance per unit length is 400 nH/m. As a consequence, a total of 2 mm of waveguide for the qubit is needed (1 mm per capacitance to ground). Waveguides also have inductance, but the total inductance of the waveguide is small, only around 6% of the Josephson inductance, which is good.

In FIG. 5 two of the circuit structures illustrated in FIG. 3(c) are arranged side by side so as to share a planar common ground electrode region 4. A linear portion of the strip forming the second electrode region 3′ of the left circuit structure and a linear portion of the strip forming the first electrode region 3 of the right circuit structure extend along a common linear center line so that their free end portion 16′ and 16 face each other at a distance of, for example, 100 μm. This causes a direct capacitive coupling between the left and right circuit structures.

In the embodiment of FIG. 6 a tuneable coupler 17, for example a tuneable transmon, is positioned between the free end portions 16′, 16 of the strips with result that the latter ones are capacitively coupled to the coupler 17. The latter one is connected to a third electrode region 18 that has the shape of a strip of uniform width and extends alongside the strips forming the first and second electrode regions 3, 3′ and is separated from the latter ones by the gap 15 on one of its rectangular sides. On the remaining three rectangular sides it is separated from the common ground electrode region 4 by an insulating gap 15′ so as to be capacitively coupled to the common ground electrode region 4. Typical dimensions in the direction of the strips and in the orthogonal direction of the strips are L=602 μm and S=40 μm, respectively.

The embodiment illustrated in FIG. 7 is similar to the one of FIG. 6 with the exception that the third electrode region 18 illustrated in FIG. 6 is modified to include first and second strips 19, 19′ of essentially uniform width that extend on both sides alongside the strips 3, 3′ forming the first and second electrode regions, respectively. The rectangular sides of the strips 19, 19′ that face the first and second strips 3, 3′ are separated from the latter ones by the insulating gap 15. The remaining three rectangular sides facing the common ground electrode region 4 are separated from the latter one by additional insulating linear gaps 15′. Typical dimensions of the strips 19, 19′ are L=302 μm and S=40 μm in the lengthwise and widthwise directions, respectively.

In the embodiments of FIGS. 6 and 7 desired values of the capacitive couplings may be obtained by appropriate dimensioning of the first, second and third electrode regions, specifically a direct capacitive coupling between the left and right circuit structures in the range of 0.1 fF, the coupling between the coupler and each of the left and right circuit structures in the range of 6 fF and a self-capacitance of the coupler in the range of 80 fF.

List of Reference Signs

| | |
|---|---|
| 1 | Josephson junction region |
| 2 | SQUID-loop |
| 3, 3′ | capacitor plates/first and second electrode regions |
| 4 | opposite capacitor plates/common ground electrode region |
| 5, 5′ | intermediate section |
| 6, 6′ | intermediate section |
| 10, 11 | legs |
| 12 | connecting portion |
| 13 | bisector curve |
| 13a, 13b | outermost point |
| 14 | circle/central portion |
| 15, 15′ | gap |
| 16, 16′ | free end portion |
| 17 | tuneable coupler |
| 18 | third electrode region |
| 19, 19′ | strips |

1-19. (canceled)

20. A planar electrically floating qubit circuit structure, comprising:
a Josephson junction region including first and second weakly coupled superconductors;
first and second electrode regions galvanically coupled to said first and second superconductors, respectively; and
a ground electrode region;
wherein a series capacitance of said first and second electrode regions to said ground electrode region is greater than a self-capacitance of said Josephson junction region.

21. The circuit structure according to claim 20, wherein said Josephson junction region has a surface area that is less than a surface area of each of said first and second electrode regions.

22. The circuit structure according to claim 21, wherein said first and second electrode regions have a geometrical arrangement that is centrally symmetric with respect to a centroid of the surface area of said Josephson junction region.

23. The circuit structure according to claim 20, wherein each of said first and second electrode regions is shaped as a continuous strip of essentially uniform width that extends between a connecting portion thereof, which is located adjacent to said Josephson junction region for galvanic connection thereto, and at least one free end portion thereof, which is located remote from said Josephson junction region.

24. The circuit structure according to claim 23, wherein said at least one free end portion includes first and second free end portions, said connecting portion of said strip being located half-way therebetween.

25. The circuit structure according to claim 24, wherein directions of extension of said strip from the connecting portion to the first and second free end portions are essentially mutually orthogonal.

26. The circuit structure according to claim 24, wherein a direction of extension of said strip is a mean linear direction, said strip meandering about said linear direction between said connecting portion thereof and each one of said free end portions thereof.

27. The circuit structure according to claim 20, wherein said ground electrode region and each of said first and second electrode regions is arranged so as to form a microstrip waveguide.

28. The circuit structure according to claim 20, wherein said ground electrode region and each of said first and second electrode regions is arranged so as to form a coplanar waveguide.

29. The circuit structure according to claim 20, wherein said qubit circuit is a fixed-frequency transmon or a tuneable transmon.

30. A combination, comprising: a tuneable coupler; and two circuit structures according to claim 20, wherein at least one of said first and second electrode regions of one of said two circuit structures is capacitively coupled to the tuneable coupler that is capacitively coupled to one of said first and second electrode regions of the other one of said two circuit structures.

31. The combination according to claim 30, wherein each of said first and second electrode regions is shaped as a continuous strip of essentially uniform width that extends between a connecting portion thereof, which is located adjacent to said Josephson junction region for galvanic connection thereto, and at least one free end portion thereof, which is located remote from said Josephson junction region, wherein said at least one free end portion of said strip forming one of said first and second electrode regions of said one of said two circuit structures and said at least one free end portion of said strip forming one of said first and second electrode regions of said other one of said two circuit structures are located adjacent to said coupler for capacitive coupling thereto.

32. The combination according to claim 31, wherein a distance between said free end portions is dimensioned so as to result in a desired value of the capacitive coupling.

33. The combination according to claim 31, wherein the strips that extend between said connecting portions and said at least one free end portions extend along a common linear center line.

34. The combination according to claim 30, further comprising a third electrode region that is capacitively coupled to said common ground electrode region and to said first and second electrode regions that are capacitively coupled to said tuneable coupler, wherein said tuneable coupler is connected to the third electrode region, said third electrode region being dimensioned so as to result in desired values of self-capacitance of the tuneable coupler and the coupling capacitances between said one and said other one of said qubit circuit structures and said tuneable coupler, respectively.

35. The combination according to claim 34, wherein said third electrode region extends adjacent to and along the strips whose free end portions are located adjacent to said coupler.

36. The combination according to claim 35, wherein the third electrode region is shaped as a strip of essentially uniform width that longitudinally extends alongside the strips whose free end portions are located adjacent to said coupler.

37. The combination according to claim 35, wherein the third electrode region is shaped as first and second strips of essentially uniform width that longitudinally extend on both sides alongside the strips whose free end portions are located adjacent to said coupler.

38. The circuit structure according to claim 30, wherein said ground electrode region and at least one of said first and second electrode regions, respectively, extend in a common plane with adjacent boundaries thereof so as to define an insulating gap therebetween.
